(19) United States
(12) Patent Application Publication
(10) Pub. No.: US 2026/0257920 A1
(43) Pub. Date: Sep. 3, 2026

(54) A DIELECTRIC MATERIAL AND METHOD OF FORMING THE SAME

(71) Applicant: NATIONAL UNIVERSITY OF SINGAPORE, Singapore (SG)

(72) Inventors: Barbaros OEZYILMAZ, Singapore (SG); Chee Tat TOH, Singapore (SG); Artem GREBENKO, Singapore (SG); Ugur KARADENIZ, Singapore (SG)

(73) Assignee: NATIONAL UNIVERSITY OF SINGAPORE, Singapore (SG)

(21) Appl. No.: 19/491,244

(22) PCT Filed: Jun. 7, 2024
(86) PCT No.: PCT/SG2024/050371

§ 371 Date: Dec. 8, 2025

(30) Foreign Application Priority Data
Jun. 8, 2023 (SG) 1020301619T

(51) Int. Cl. C01B 32/05; C23C 16/26

(52) U.S. Cl. CPC C01B 32/05; C23C 16/26; C01P 2002/02; C01P 2002/82; C01P 2002/84; C01P 2004/04; C01P 2006/40

(57) ABSTRACT

A dielectric material and method of forming the same There is provided a dielectric material comprising a film comprising a layer of two-dimensional (2D) material, wherein the film has dielectric constant (κ)≤3.0. There is also provided a method of forming the dielectric material.

### TECHNICAL FIELD

The present invention relates to a dielectric material and a method of forming the same.

### BACKGROUND

Conventionally, porosity of dielectric materials is increased to achieve a reduction in the dielectric constant. However, this trade-off is detrimental to the device fabrication and structure, particularly mechanical strength, but is still used because of the lack of an alternative material.

Existing dielectric materials are also unable to scale down in thickness without sacrificing the dielectric constant property.

Thus, there is a need for an improved dielectric material and method of forming the same.

### SUMMARY OF THE INVENTION

The present invention seeks to address these problems, and/or to provide an improved dielectric material, particularly a dielectric material comprising a two-dimensional (2D) material.

According to a first aspect, the present invention provides a dielectric material comprising a film comprising a layer of two-dimensional (2D) material, wherein the film has dielectric constant (K)≤3.0.

According to a particular aspect, the 2D material may comprise monolayer amorphous carbon (MAC).

The film may have a thickness of ≤20 nm. For example, the film may have a thickness of 0.5-3 nm.

In particular, the film may comprise at least two layers of 2D MAC. For example, the film may comprise two to five layers of 2D MAC.

The film may have a hardness of >10 GPa. The film may have a dielectric strength of >8 MV cm⁻¹.

According to a particular aspect, the film may be non-porous.

According to a particular aspect, the film may be formed on at least a portion of a non-catalytic substrate. In particular, the non-catalytic substrate may comprise a silicon-based substrate, a carbon-based substrate, a metal-based substrate, oxides, transition metal dichalcogenides, mxenes, or any combination thereof. For example, the non-catalytic substrate may comprise cobalt, gold, copper, nickel, tungsten, molybdenum, ruthenium, niobium, silicon dioxide, silicon nitride, titanium nitride, tantalum nitride, cobalt oxide, tungsten carbide, germanium, gallium arsenide (GaAs), silver, stainless steel, Fernico, manganese, aluminium, or any combination thereof.

According to a second aspect, there is provided a method of forming the dielectric material, the method comprising depositing carbon radicals on a substrate.

According to a particular aspect, the method may further comprise repeating the depositing carbon radicals to form up to five layers of 2D MAC.

According to another particular aspect, the depositing carbon radicals may comprise forming carbon radicals via photodissociation of a carbon source. The depositing carbon radicals may comprise forming carbon radicals via UV wavelength absorption of a carbon source. In particular, the UV wavelength may be 200-400 nm. The carbon source may comprise acetylene, methane, acetylene, ethylene, ethanol, propane, adventitious carbon, or any combination thereof.

According to a particular aspect, the substrate may comprise a non-catalytic substrate. In particular, the non-catalytic substrate may comprise a silicon-based substrate, a carbon-based substrate, a metal-based substrate, oxides, transition metal dichalcogenides, mxenes, or any combination thereof. For example, the non-catalytic substrate may comprise cobalt, gold, copper, nickel, tungsten, molybdenum, ruthenium, niobium, silicon dioxide, silicon nitride, titanium nitride, tantalum nitride, cobalt oxide, tungsten carbide, germanium, gallium arsenide (GaAs), silver, stainless steel, Fernico, manganese, aluminium, or any combination thereof.

The depositing may be in a plasma environment. According to a particular aspect, the method may further comprise generating the plasma environment prior to the depositing. For example, the plasma environment may comprise remote inductively-coupled plasma.

### BRIEF DESCRIPTION OF THE DRAWINGS

In order that the invention may be fully understood and readily put into practical effect there shall now be described by way of non-limitative example only exemplary embodiments, the description being with reference to the accompanying illustrative drawings. In the drawings:

FIG. 1 shows direct growth of monolayer amorphous carbon; FIGS. 1(a)-(c) show cross-section transmission electron microscopy (TEM) images of 3L, 2L, and 1L (layer) thickness of MAC on SiO₂/Si respectively, where EELS map overlay shows distribution of C and O₂ for precise thickness determination; FIG. 1(d) shows a 4-inch Si/SiO₂ wafer largely covered with 1.5 nm MAC layer (ML-AC), clearly distinguishable from the substrate by optical contrast (i.e., ML-AC represents a first segment, SiO₂ represents a second segment, where the second segment is at the side portion of the wafer); FIG. 1(e) shows atomic force microscopy (AFM) thickness measurements of directly grown 1-4L MAC film on SiO₂ as a function of growth time, with each layer numbered where 1L is represented with 1a and 1b, 2L represented with 2a and 2b, 3L represented with 3a to 3d, and 4L represented with 4a to 4d (letters near each layer number indicate completeness; maximum completeness for monolayer and bilayer is achieved at letter “b”, and for more layers at “d”); FIGS. 1(f)-(j) show top-view TEM images with atomic resolution illustrating layer-by-layer growth in sequence: FIGS. 1(f), 1(h), 1(j) correspond to complete 1L, 2L and 3L layers of MAC, FIGS. 1(g) and 1(i) correspond to incomplete second and third layers, respectively, with growth transitioning from 1L to 2L for the second layer and 2L to 3L for the third layer over time; FIGS. 1(k)-(m) show scanning transmission electron microscopy (STEM) imaging of a 1L, 2L and 3L MAC after transfer from SiO₂, respectively;

FIGS. 2(a)-(l) show AFM analysis of the thickness of MAC as a function of time, with synthesis time and number of layers indicated;

FIG. 3 shows a summary of spectroscopy analysis of MAC samples; FIG. 3(a) shows typical Raman spectra for different growth durations (numbers with letters on the right side of each line indicate layer and its completeness); FIG. 3(b) shows an optical image of a set of metal lines covered with MAC, with metal lines shown in the inset; FIG. 3(c) shows individual Raman spectra collected from SiO₂ surface, Cu surface and Co surface (inset shows scheme of FIG. 3(b)); FIG. 3(d) shows C1 s line as a function of growth time (numbers with letters on the right side of each line indicate layer and its completeness), and samples match FIG. 1; FIG. 3(e) shows similarity of C 1s line of MAC grown on metallic and insulating substrates; FIG. 3(f) shows NEXAFS spectra for monolayer (solid line) and four-layer samples (dashed line), with dependence of the 1s-π* and 1s-σ* transition on the incidence angle (for the monolayer sample, the experiment geometry is shown in the inset);

FIG. 4 shows uniform growth of MAC; FIG. 4(a) shows EELS carbon k-edge spectra of 1L, 2L and 3L samples corresponding to FIGS. 1(a)-(c); FIGS. 4(b) and 4(c) show uniform character of Raman signal across the entire 4-inch wafer, with points on the wafer marked p1, p2 and p3 and spectra collected from these points; FIG. 4(d) shows AFM image of close-to-atomically smooth surface of the MAC film grown on Si/SiO₂; FIGS. 4(e)-(g) show pristine and pure state of growth substrates after MAC deposition for the case of Co, Cu and Si respectively;

FIG. 5 shows hardness of MAC; FIG. 5(a) shows hardness measured by AFM indentation of 2.1 nm thick film of MAC on SiO₂ compared with the SiO₂-only reference sample; FIGS. 5(b)-(c) shows AFM morphology of equivalent indentations for SiO₂ and MAC on SiO₂;

FIG. 6 shows a schematic of a metal interconnect stack, with the low-K dielectric surrounding conductive elements, and in the inset, complex structure of multiple layers surrounding each line is revealed, and with a simplified structure exemplified on the right-hand side as represented in the zoomed region;

FIG. 7 shows conformal coating by MAC; FIGS. 7(a)-(c) show cross-section TEM and corresponding EELS map indicating conformal coating of the trench in silicon dioxide;

FIGS. 8(a)-(c) show cross-section TEM and corresponding EELS map indicating conformal coating of cobalt line with MAC layer; FIG. 8(a) shows a wide scan overview of several lines covered with ML-AC; FIG. 8(b) shows a zoomed in view on one of the lines; FIG. 8(c) shows EELS overlay with layers indicated;

FIGS. 9(a)-(b) show AFM images, and thickness profile over time, of 80 nm thick cobalt lines on Si/SiO₂ substrate without (left), and with 1.5 nm MAC layer (right), after exposure to ambient conditions for 72 hours, respectively;

FIGS. 10(a)-(b) show a set of 100 nm wide copper lines with and without protection by ML-AC layer, respectively, after exposure for 30 seconds to 7% APS solution;

FIG. 11 shows dielectric and metal diffusion barrier performance of directly grown MAC; FIG. 11(a) shows low-frequency dielectric spectroscopy data where dielectric permittivity κ~1.34 is independent of MAC thickness; FIG. 11(b) shows capacitance as a function of frequency for various thicknesses, and impedance hodograph measured for MAC is shown in the inset, where MAC capacitance does not change in the frequency range of 100 Hz to 100 kHz; FIG. 11(c) shows dependence of the breakdown voltage on the dielectric thickness, which indicates dielectric strength of 28-31 MV cm⁻¹; FIG. 11(d) shows copper ion diffusion experiments proving at least two orders of magnitude of the time-to-failure improvement from existing 10 years benchmarking value when ln(TTF)~E and ln(TTF)~\sqrt{E} model is applied (triangle symbols (SiO₂) illustrating a comparison of the substrate behaviour); FIG. 11(e) shows a comparison of the linear model fit of TTF for the most recently reported replacements of existing tunnelling barrier (TaN, indicated by triangles pointing to the left, and hBN, indicated by triangles pointing to the right);

FIG. 12 shows optical characterisation of dielectric permittivity; FIG. 12(a) shows optical ellipsometry data of imaginary and real part of the dielectric permittivity supporting results obtained in the low-frequency range; FIGS. 12(b)-(c) show dielectric spectroscopy fit of Psi and Delta spectra collected at different incidence angles by Cody-Lorentz-Urbach model (angle increased from top curve to bottom curve from 40 to 70 degrees with 5 degree step, and other layers considered in the model are reflective surface of silicon substrate and silicon dioxide with 87.4 nm thickness as determined by cross-section TEM measurements); FIGS. 12(d)-(e) show UV-vis spectroscopy data for MAC of various thickness; FIG. 12(e) shows data in the form of Tauc plot and corresponding direct band gaps were extracted;

FIG. 13 shows breakdown and leakage measured in MIM devices; FIG. 13(a) shows optical image showing MIM capacitors (Au metal plates) with a 50×50 μm² d, 500×500 nm² h, varying capacitor plate area; FIGS. 13(b) and (f) show I-V curves measured for devices shown in 13(a) and 13(d), respectively circles (1L) represent monolayers, crosses (2L) represent bilayers, stars (3L) represent trilayers and squares (4L) represent four layers, horizontal and vertical dashed line in (b) represents the low-power limit current density of 1.5×10⁻² A cm⁻² and 0.7 V transistor operation voltage, and acceptable transistor operational range is within the bottom right quadrant); FIGS. 13(c) and (g) show Weibull plots of the breakdown voltage extracted from 13(b) and 13(f), respectively; FIGS. 13(h)-(j) show I-V curves for scaling capacitor plate size for 1, 2 and 3 layers, respectively; and

FIG. 14 shows breakdown and leakage current measurement with CP-AFM; FIG. 14(a) shows a schematic of CP-AFM experiment; FIG. 14(b) shows I-V curves of 1, 2 and 3-layer MAC on Au substrate (over 100 data points each, and solid lines indicate averaged curves); FIG. 14(c) shows Weibull plot of the data presented in 14 (b).

### DETAILED DESCRIPTION

As explained above, there is a need for an improved dielectric material.

In general terms, the present invention provides a dielectric material comprising a film comprising a layer of two-dimensional (2D) material, wherein the film has dielectric constant (κ)≤3.0. An ultralow-κ material (κ<2.5) that can be <3 nm thick is desired for use in next generation integrated circuits (IC). However, generally, it is difficult to scale down the thickness of a dielectric material without increasing κ. The dielectric material of the present invention advantageously has low κ with low thickness, and at the same time is non-porous, has superior mechanical properties, and is resistant to corrosion.

According to a first aspect, the present invention provides a dielectric material comprising a film comprising a layer of two-dimensional (2D) material, wherein the film has dielectric constant (κ)≤3.0.

For the purposes of the present invention, the use of the singular includes the plural unless specifically stated otherwise. It should be noted that, as used in the specification and the appended claims, the singular forms “a”, “an” and “the” include plural referents unless the context clearly dictates otherwise. Further, the use of the term “including”, “comprising”, and “having” as well as other forms, such as “include”, “comprise”, “have” are not considered limiting.

For the purposes of the present invention, references to 2D material refers to a material with single atomic layer thickness. The 2D material may have an in plane amorphous structure.

The film may have κ≤3.0. For example, the film may have κ≤2.5. In particular, the film may have κ≤2.0, κ≤1.9, κ≤1.8, κ≤1.7, κ≤1.6, κ≤1.5, κ≤1.4, κ≤1.3. Even more in particular, the film may have κ≤1.3. The film may comprise one or more layers of 2D material. According to a particular aspect, the dielectric material may comprise a film and any suitable non-2D material with κ≤3.0. According to another particular aspect, the dielectric material may comprise a film and any suitable non-2D material with κ>3.0. The non-2D material may comprise a wafer or any suitable substrate which is non-catalytic.

The 2D material may be any suitable amorphous 2D material. The 2D material may have κ≤3.0. According to a particular aspect, the 2D material may comprise monolayer amorphous carbon (MAC). For the purposes of the present invention, MAC is defined as an analogue of monolayer crystalline carbon (graphene), with dominantly sp2 like carbon and random orientation of in-plane bonds, where π bonds are disrupted and relative contribution of σ bonds to the material properties is increased and low-polar carbon bonds in a disordered structure minimizes the total polarizability. As MAC contains only carbon, there is advantageously no diffusion problems and is compatible with many different substrates. MAC may have any suitable interlayer spacing. For example, MAC may have an interlayer spacing of 0.6-0.9 nm. In particular, the interlayer spacing may be 0.65-0.85 nm, 0.65-0.8 nm, 0.7-0.75 nm. The interlayer spacing may be about twice that of graphene. In each single layer of 2D MAC, the MAC may have a similar number of carbon atoms as each single layer of its analogue monolayer crystalline carbon (graphene). Accordingly, MAC may have about half the density of graphene. In particular, MAC may have a density of 0.6-1.5 g cm-3. Thus, using MAC, or any other suitable amorphous 2D material, such as monolayer amorphous boron nitride, beneficially lowers the material density and at the same time allows low κ to be obtained.

The film comprised in the dielectric material may have any suitable thickness. For example, the film may have a thickness of ≤20 nm. In particular, the film may have a thickness of ≤10 nm, ≤9 nm, ≤8 nm, ≤7 nm, ≤6 nm, ≤5 nm, ≤4 nm, ≤3 nm, ≤2 nm, ≤1 nm. Even more in particular, the film may have a thickness of ≤3 nm. The film may have a thickness of 0.5-3 nm, 0.65-2.6 nm, 0.8-2.4 nm, 1.3-2.1 nm, 1.5-2 nm. The film may comprise any suitable number of layers of 2D MAC. For example, the film may comprise one or more layers of 2D MAC. In particular, the film may comprise one, two, three, four, or five layers of 2D MAC. There are various specific thickness requirements based on the scaling technology node and the dimension for optimal performance, and the dielectric material of the present embodiments advantageously allow different thicknesses to be grown by adjusting the number of single atomic thick MAC layers.

Each of the one or more layers of 2D MAC may have κ≤3.0. Thus, the film may have κ ≤3.0, as described above.

The film comprised in the dielectric material may have a suitable hardness. For example, the film may have a hardness of >10 GPa. In particular, the film may have a hardness of >20 GPa, >30 GPa, >40 GPa, >50 GPa, >60 GPa, >70 GPa, >80 GPa, >90 GPa, >100 GPa. Even more in particular, the film may have a hardness of about 100 GPa. The mechanical stability enables standard device fabrication of integrated circuits without collapse of the dielectric material.

As explained above, in integrated circuits, reducing the thickness of the dielectric layer typically result in higher leakage current that reduce performance. The dielectric material of the present embodiments advantageously enables device scaling with a higher dielectric strength to prevent the increase in leakage current. In particular, the film may have a high dielectric strength to allow it to meet the requirement at down to a single atomic layer thickness. For example, the film may have a dielectric strength of >8 MV cm⁻¹. The film may have a dielectric strength of >10 MV cm⁻¹, >15 MV cm⁻¹, >20 MV cm⁻¹, >25 MV cm⁻¹, >30 MV cm⁻¹. Even more in particular, the film may have a dielectric strength of >30 MV cm⁻¹.

The film comprised in the dielectric material may be non-porous. For the purposes of the present invention, references to non-porous refers to an absence of pores on and within the film. The absence of pores may be, but is not limited to, absence of pores or holes with dimensions of around 1 nm or larger. The non-porous film advantageously allows improved resistance to degradation caused by moisture absorption or ion diffusion into the film. Further, additional layers of barrier (against metal ion diffusion) and liner materials (for adhesion of dielectric material to the device structure), which further limit the size scaling of the integrated circuits, will not be required since the film is resistant to such degradation. A simplified device architecture of metal in direct contact with the dielectric material can be achieved, which allows for better interconnects performance, either with larger volume for metal lines to improve line conductivity or more aggressive size scaling.

According to a particular aspect, the film may be formed on at least a portion of a non-catalytic substrate. For the purposes of the present invention, references to non-catalytic substrate refer to any suitable substrate which does not participate in the growth chemistry. In particular, the substrate may be considered non-catalytic and does not participate in growth chemistry at temperature conditions used when forming the film, even though it may be catalytically active at higher temperatures above those for forming the film. The non-catalytic substrate may not have κ≤3.0. Examples of suitable non-catalytic substrates include, but is not limited to, a silicon-based substrate, a carbon-based substrate, a metal-based substrate, oxides, transition metal dichalcogenides, mxenes, or any combination thereof. In particular, the non-catalytic substrate may comprise cobalt, gold, copper, nickel, tungsten, molybdenum, ruthenium, niobium, silicon dioxide, silicon nitride, titanium nitride, tantalum nitride, cobalt oxide, tungsten carbide, germanium, gallium arsenide (GaAs), silver, stainless steel, Fernico, manganese, aluminium, or any combination thereof. Even more in particular, the non-catalytic substrate may comprise silicon dioxide, silicon nitride, titanium nitride, copper, cobalt and tungsten.

According to a second aspect of the present invention, there is provided a method of forming a dielectric material of the first aspect, the method comprising depositing carbon radicals on a substrate. For the purposes of the present invention, references to carbon radicals refer to carbon species with one unpaired electron and which readily reacts with other atoms or molecules. The depositing may be by any suitable means. For example, the depositing may be by chemical vapour deposition (CVD). In particular, the depositing may be by laser-plasma enhanced chemical vapour deposition (LPE-CVD), laser CVD (LCVD), UV lamp-assisted CVD, or UV lamp-plasma assisted CVD.

The depositing carbon radicals may be for any suitable amount of time to enable one or more layers of 2D material to be formed on the substrate, thereby forming the dielectric material. For example, the depositing carbon radicals may be for >1 minute. In particular, the depositing carbon radicals may be for >1.5 minutes, >2 minutes, >2.5 minutes, >3 minutes, >3.5 minutes, >4 minutes, >4.5 minutes, >5 minutes, >5.5 minutes, >6 minutes, >6.5 minutes, >7 minutes, >7.5 minutes, >8 minutes, >8.5 minutes, >9 minutes, >9.5 minutes, >10 minutes, >11 minutes, >12 minutes, >13 minutes, >14 minutes, >15 minutes, >16 minutes, >17 minutes, >18 minutes, >19 minutes, >20 minutes. According to a particular aspect, the method may comprise repeating the depositing to form up to five layers of 2D MAC.

The depositing carbon radicals may be for any suitable time at any suitable step growth increments until the desired number of layers is achieved. For example, the depositing carbon radicals may be increased from tᵢ minutes (initial time) to t_{f} minutes (final time), in duration of 1-minute increments, 2-minute increments, or any combination thereof. In particular, the step growth increments may be varied in alternating intervals, such as 1-minute, 2-minute, 1-minute, 2-minute, and repeated until tr is reached. This would mean fewer steps but at the same time achieving increased homogeneity of each layer.

The depositing of carbon radicals may comprise forming of carbon radicals via photodissociation of a carbon source. The photodissociation of a carbon source may be via any suitable light source with any suitable wavelengths. For example, the light source may be excimer lasers, halogen lamps, diode-lamps, diode lasers, gas lasers. For example, the wavelength of the light source may be 0.01-2500 nm. In particular, the wavelength of the light source may be 0.01-0.1 nm, 0.1-1 nm, 0.1-2000 nm, 1-1500 nm, 10-1000 nm, 100-500 nm, 150-450 nm, 200-400 nm, 250-350 nm. In particular, the depositing of carbon radicals may comprise forming of carbon radicals via UV wavelength absorption of a carbon source. The UV wavelength may be any suitable UV wavelength to cause carbon radicals to form when exposing a carbon source to the UV wavelength. For example, the UV wavelength may be 200-400 nm. The UV wavelength may be generated by any suitable equipment. For example, the UV wavelength may be generated by excimer laser or UV lamp. The excimer laser source may comprise XeCl or KrF. The carbon source may be any suitable carbon source capable of forming carbon radicals under suitable conditions. For example, the carbon source may comprise acetylene, methane, acetylene, ethylene, ethanol, propane, adventitious carbon, or any combination thereof. In particular, the carbon source may comprise acetylene. By using acetylene as a carbon source, the concentration of C2 radicals is advantageously increased, self-limiting decomposition behaviour is disrupted which allows the growth of multiple layers of MAC, and a catalyst is not required.

The depositing carbon radicals may be at any suitable pressure selected based on the carbon source. For example, the depositing carbon radicals may be at a pressure of 10⁻³ to 10⁻².

According to a particular aspect, the substrate may comprise a non-catalytic substrate. The non-catalytic substrate may be as described above. The substrate may be considered non-catalytic and does not participate in growth chemistry at a temperature of about 20-500° C., even though it may be catalytically active at higher temperatures. In particular, the substrate may be considered non-catalytic at a temperature of about 50-450° C., 100-400° C., 150-350° C., 200-300° C. Even more in particular, the substrate may be considered non-catalytic at a temperature of about 250-350° C.

The substrate may be directly exposed to the UV wavelength as described above. In an alternate aspect, direct exposure of the substrate to the UV wavelength may also be avoided, to prevent possible surface damage.

The depositing of carbon radicals may be in a plasma environment. A plasma environment advantageously provides additional energy to the carbon radicals. Thus, a higher portion of carbon radicals will be in the optimal energy range for photodissociation by the specific wavelength UV source to increase the concentration of active carbon radicals and thereby facilitate deposition on substrates. According to a particular aspect, the method may further comprise generating the plasma environment prior to the depositing. For example, the generating the plasma environment may comprise remote inductively-coupled plasma.

Thus, the method is an improved method which allows direct and conformal growth of the film. This is particularly important for applications in integrated circuits, where the film must cover all around the trenches and vias, and hence it needs to be able to grow continuously and connected on all sides of any high aspect ratio device structure, such as, but not limited to, pre-patterned pillars and trenches. The method allows exclusion of liner materials typically used to promote conformal growth, but which is not ideal in many deposition methods. Further, the growth of the film occurs in the whole volume, therefore the direct hitting of the surface with excimer laser is eliminated, which is a critical feature for any further industrial application.

Having now generally described the invention, the same will be more readily understood through reference to the following example which is provided by way of illustration, and is not intended to be limiting.

### Example

### Materials and Methods

Non-catalytic direct growth was performed by chemical vapour deposition (CVD) set-up chamber operated at a base pressure level of 10⁻⁸ to 10⁻⁷ mbar. UV excimer XeCl laser (λ=308 nm) was used to initiate photodecomposition of carbon source (Acetylene, C₂H₂), and a remote inductively-coupled plasma (PIE Scientific) source was used to introduce Ar plasma to the set-up. Samples were mounted on a stainless-steel holder (2 modes of operation, direct and indirect exposure of the sample to the laser). For the case of Cu foils, Si, and Si/SiO₂ substrates, the surfaces of the samples were directly exposed to the excimer laser. For the same substrates or for fabrication of devices in the indirect exposure mode, direct exposure of the surface to laser radiation was avoided to prevent possible surface damage. Since the laser also dissociates the carbon source when it is in the vicinity of the sample but not in contact with the laser, the same conditions can be used, but stage heating of up to 300° C. was used to support the growth.

Monolayer amorphous carbon growth was achieved by excimer laser photolytic decomposition of carbon source. Acetylene was used to increase the concentration of C₂ radicals and remote inductively coupled plasma was added, which helped to increase both the concentration and activity of carbon radicals and facilitate deposition on the substrate, e.g. silicon oxide.

Similar results for MAC synthesis were also obtained with the replacement of the excimer laser (XeCl or KrF source) with a UV lamp source.

### Characterization

Cross-section transmission electron microscopy (TEM) images (FIGS. 1(a)-(c)), taken from arbitrary locations on the uniformly covered 2 inch wafer (FIG. 1(d)) with elemental mapping by electron energy loss spectroscopy (EELS, insets of FIGS. 1(a)-(c)), atomic force microscopy (AFM) (FIG. 1(e) and FIG. 2) and ellipsometry measurements were used to investigate the different MAC thicknesses. More than 10 samples in cross-section TEM and more than 20 samples by AFM and ellipsometer were measured, and the thicknesses corresponded to layered MAC. Three representative samples with thicknesses corresponding to 3, 2 and 1 layers of MAC (3L, 2L, and 1L, respectively) are as shown in FIGS. 1(a)-(c). EELS maps, demonstrated in the inset of each panel, enhanced the accuracy of the thickness determination, with red corresponding to the sp2 shoulder of carbon peak and blue corresponding to the oxygen. A discrete change of thickness was observed from 3L sample at 2.1 nm, (FIGS. 1(a)), to 2L at 1.45 nm, (FIG. 1(b)) and down to a monolayer at 0.8 nm (FIG. 1(c)). Measured thickness interval of 0.65 nm coincides with the interlayer distance, and the monolayer thickness is in agreement with previous literature. FIG. 1(e) shows the AFM thickness measurements of directly grown 1-4L MAC film on SiO₂. Order of the data points and their labels correspond to thicknesses measured by AFM—from bottom to top, growth time increased from 1 minute to 12 minutes, with 1 minute step.

Atomic resolution TEM of transferred suspended samples on Si₃N₄ TEM grids was done, to illustrate the amorphous structure. Layer-by-layer growth of ML-AC was demonstrated in the top-view images of ML-AC grown at different synthesis times (FIG. 1(f)-(j)). FIGS. 1(f), 1(h), and 1(j) correspond to completed 1L, 2L and 3L MAC layers, while FIGS. 1(g) and 1(i) showed intermediate growth times for in-progress growth for the second (1-2L) and third (2-3L) layer, respectively. Three representative examples are shown: a monolayer, transferred from SiO₂-substrate (shown in FIG. 1(k)); a bilayer, transferred from SiO₂ (shown in FIG. 1(l)), and a trilayer, transferred from SiO₂ (shown in FIG. 1(m)). Further, atomic resolution TEM images revealed connected but distorted carbon rings made up of various number of atoms. For overlapping nano-crystalline regions in each layer of a multilayer sample, local Moire-fringes can be seen. Despite the structures lacking periodicity, the structures advantageously did not have any holes or defects.

Detailed analysis of sample thickness versus time was performed on samples with patterned set of trenches etched in MAC by means of AFM (see FIG. 2). In the first 2 minutes of growth, thickness stayed the same in sub-nm range (FIGS. 2(a) and 2(b)). In the subsequent two minutes, the thickness increased by 0.65 nm, but remained similar for these two samples. This may be due to inability of AFM to resolve islands for the sample grown for 3 minutes, whereas the sample grown for 4 minutes had a complete second layer. Further, samples corresponding to growth time of 5, 6, 7 and 8 minutes (FIGS. 2(e), 2(f), 2(g), and 2(h)) all had about 2.1 nm thickness, and with increasing growth duration, the topmost layer became more complete. Finally, for the last set of samples with growth time of 9, 10, 11 and 12 minutes (FIGS. 2(i), 2(j), 2(k), and 2(l)), measured average thickness was 2.7 nm, which corresponded to 4 layers. The data was used to plot FIG. 1(e).

MAC directly grown on SiO₂ was characterized on up to cm-scale to assess its uniformity. A 4″ diameter Si/SiO₂ (90 nm thickness SiO₂) wafer was covered with a bilayer MAC. An optical photograph of the wafer is shown in FIG. 1(d), illustrating visually uniform thickness and a clear contrast between MAC covered region and the substrate. Raman mapping (10000 points), was used to confirm the amorphous nature and uniformity down to microns. FIG. 3(a) shows spectra averaged over the wafer surface for various growth durations. It is also worth noting that spectra from Cu and Co surfaces are similar to the one observed on SiO₂, and thus the surface did not influence growth mechanics (as seen in FIGS. 3(b) and 3(c)). As seen in FIG. 3(b), Raman spectroscopy mapping of G peak intensity shows the continuity of the formed MAC films on a large scale. Uniform distribution of the I_{G} across metallic lines patterned on the surface of SiO₂ can be seen. Individual spectra are shown in FIG. 3(c), further demonstrating the surprising technical effect that the present embodiments allowed for surface-independent deposition on Cu and/or Co surface, with only limited variation.

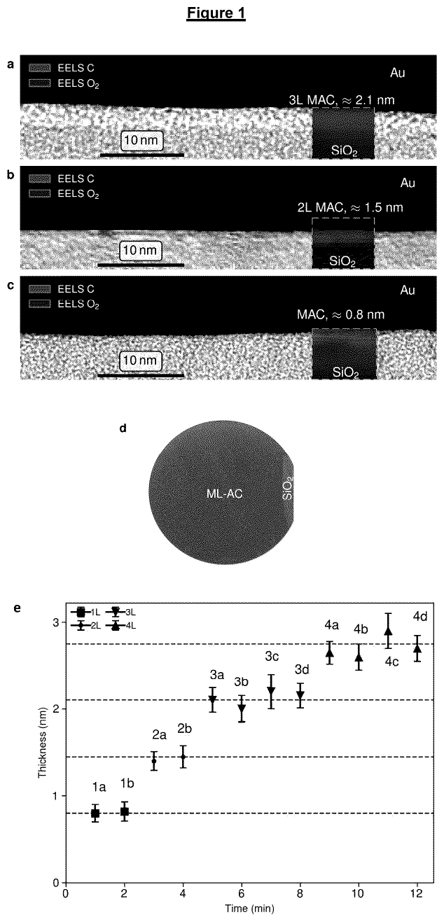

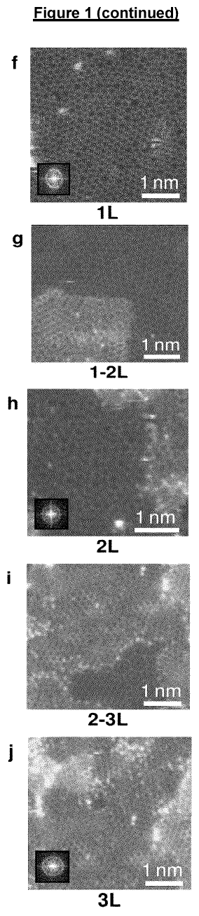

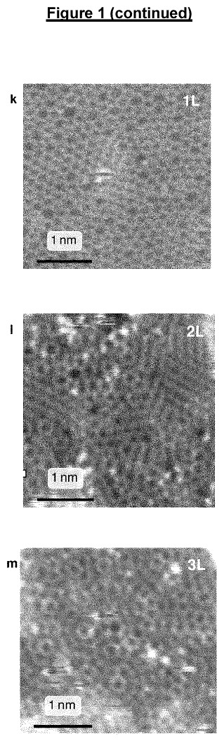

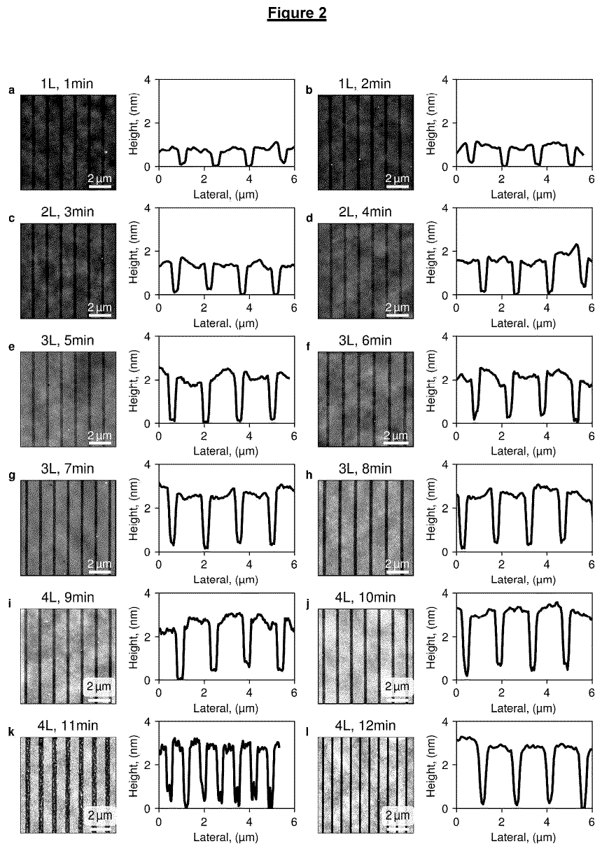

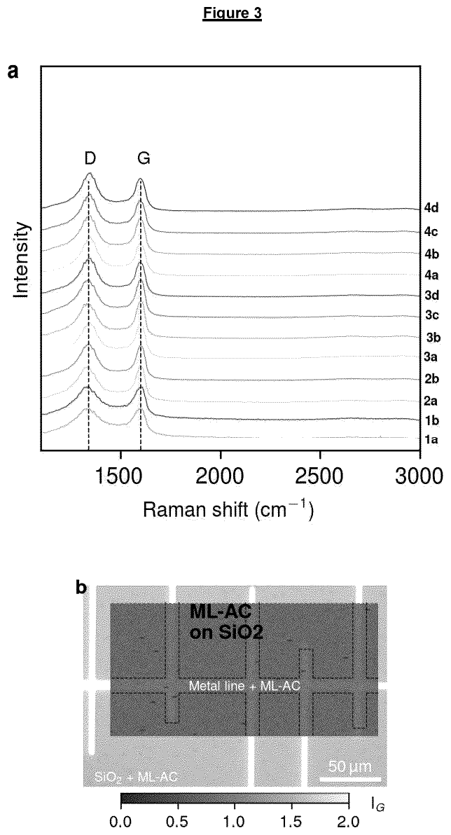

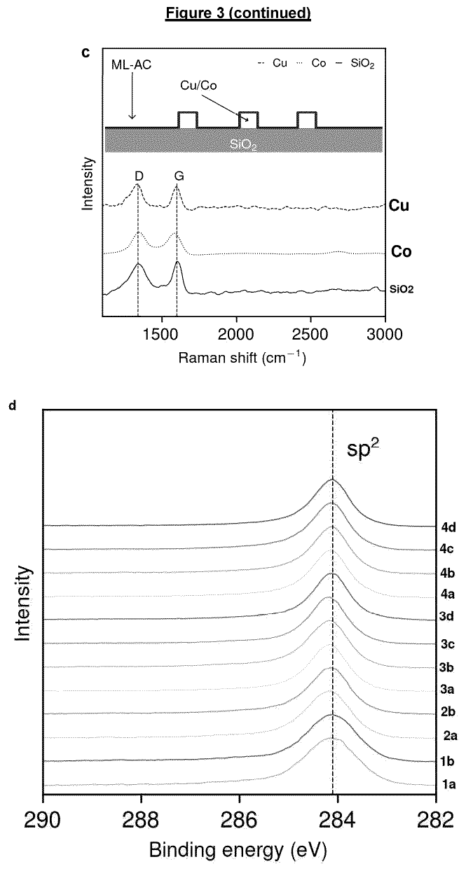

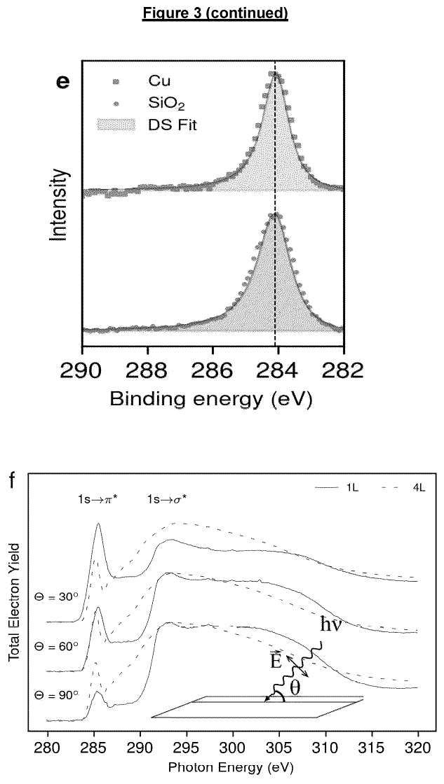

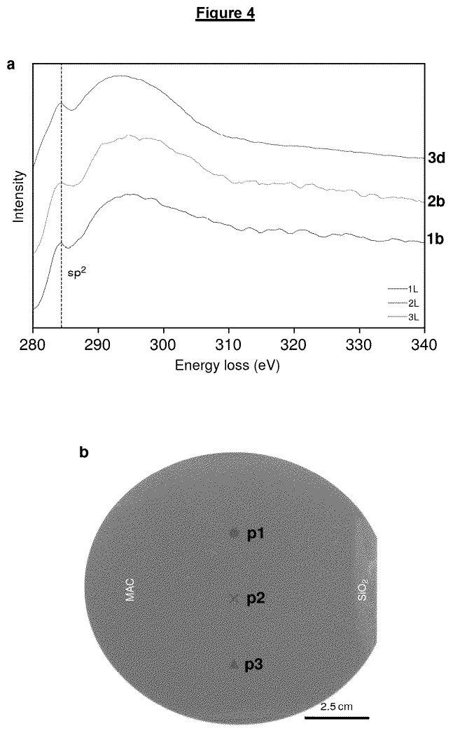

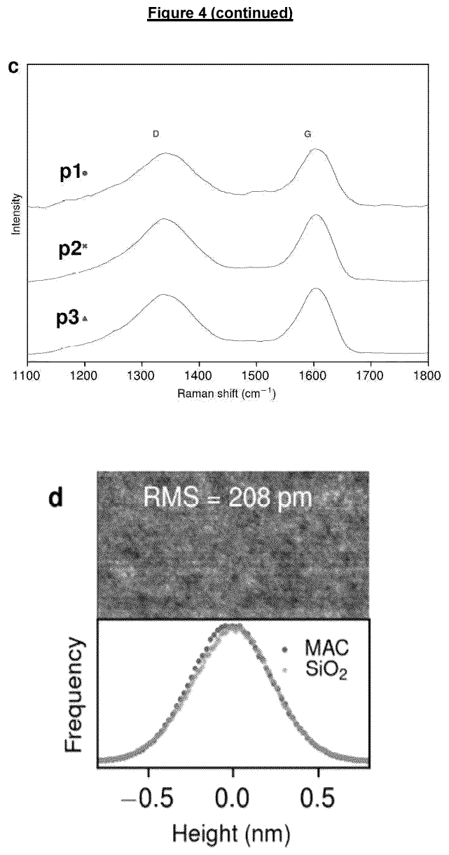

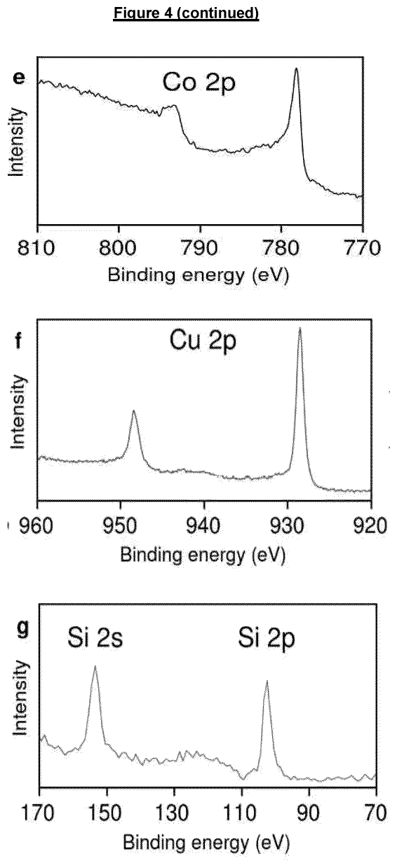

X-ray photoelectron spectroscopy (XPS) was applied to investigate elemental composition, chemical and electronic state of atoms in MAC film and substrates used for growth. XPS was used to confirm that the sample is sp2 hybridized on large scale, and it agreed with the local finding obtained by EELS. C 1s core level spectra captured for various growth times are shown in FIG. 3(d) (time increases from 1 to 12 minutes with 1 minutes step, from bottom to top). C 1s core level spectra, captured from MAC grown on different substrates, are shown in FIG. 3(e). These confirmed the sp2 hybridization of carbon, and that there is negligible, or near zero, sp3 contribution. These data, combined with the core level spectra of the substrate materials (FIGS. 4(e)-(g)) also showed that there were no bonds to substrates were formed. It can be seen from FIGS. 4(e)-(g) that there is neither bonding, nor formation of carbides or any other compounds, for the formed substrate underneath the MAC.

Near edge X-ray absorption fine structure (NEXAFS) was employed to study σ and φ bond system to prove layered nature of the MAC, and results are shown in FIG. 3(f). The behaviour seen was distinctly different from graphene, and more similar to amorphous systems where 1s-π* transition is independent of incidence angle of linearly polarized x-ray beam. As shown in FIG. 3(f), 1L and 4L layers of MAC yielded consistent total electron yield with increasing photon energy at varying degrees at intervals of 30 degrees.

From EELS spectra (FIG. 4(a)), strong sp2 shoulder (indicated by vertical dashed line) was observed at 284.4 eV for all samples with similar intensity ratio to the main carbon peak. This shows that MAC structure stayed the same for all reported thicknesses for 1L, 2L and 3L, namely, dominantly sp2 like carbon. It can be seen that the intensity over energy loss for each sample 1L, 2L and 3L corresponds uniformly despite differences in growth time 1b, 2b and 3d, respectively.

The representative points indicated by dots of different shape labelled as p1, p2 and p3 in FIG. 4(b) and the correspondingly marked Raman spectra are shown in FIG. 4(c). The three identified locations across the wafer have the same spectra with I_{D}/I_{G} ratio close to the expected value of 0.85. This further shows the surprising effect where signal is uniform and consistent throughout the entire 4-inch wafer. Growth is therefore not limited to wafer size as the results apply for 1-inch wafer or even larger-sized wafers such as 8-inch wafers.

AFM was used to measure the thickness uniformity at the micro scale, as shown in FIG. 4(d). The AFM image was featureless and the roughness value of ~200 μm coincided with that of SiO₂. Adlayers, islands and clusters were not observed, unlike for conventional amorphous thin films, and the roughness distribution was consistent over the entire wafer. The histogram of height distributions (surface roughness) for SiO₂ and MAC on SiO₂ surfaces is indistinguishable, which demonstrates conformal growth of MAC over SiO₂.

Nano-indentation AFM mode was also used to probe the hardness of deposited MAC, which is a critical mechanical criterion for the application as a dielectric in metallic interconnects. As shown in FIG. 5, the hardness was at least one order of magnitude higher than that of silicon dioxide. The unique combination of the MAC having high hardness and low κ makes it a suitable candidate for back-end-of-line integration, unlike other existing materials.

### Applications

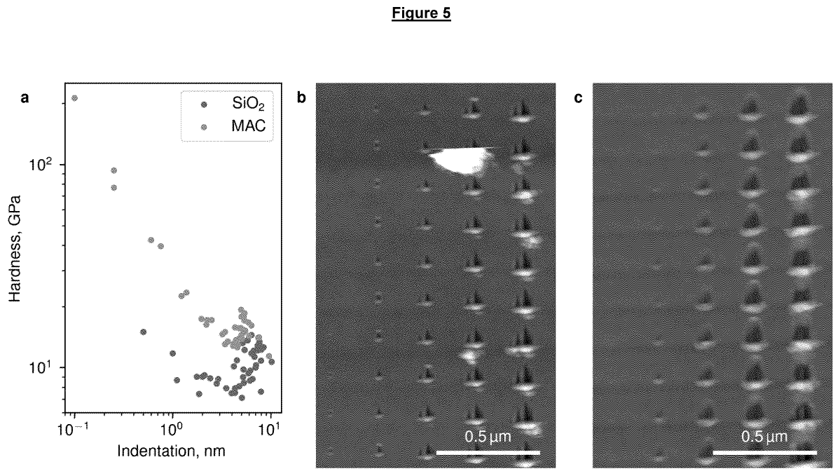

Potential applications for metal interconnects were evaluated, as schematically shown in FIG. 6. In addition to the surrounding low-K dielectric, interconnects usually have a diffusion barrier, and a liner material layers, as shown in the zoomed inset. Such an example covers the main requirements that semiconductor industry demands from the low-κ dielectric material, i.e., conformal deposition on a non-flat surface across several materials simultaneously.

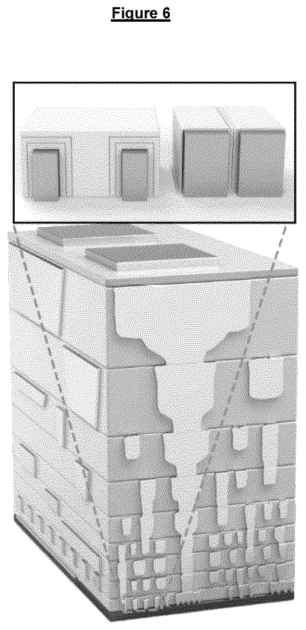

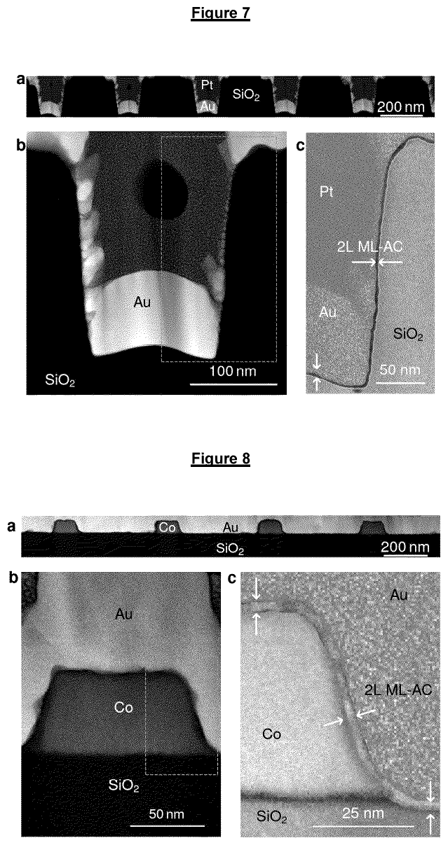

To prove capabilities of conformal coverage of the non-flat surface, 100 nm wide trenches in silicon dioxide were fabricated using electron beam lithography and fluorine-based plasma etching. Further, these trenches were covered with MAC and analysed with cross-sectional TEM combined with EELS, as illustrated in FIGS. 7(a) and 7(b). The representative data for bilayer MAC (1.5 nm) is shown. FIG. 7(a) shows a wide scan over several trenches at the same time. Each of the trench provided uniform conformal coating with consistent growth of each different materials interacting with each other. FIG. 7(b) provides a zoomed view of one of the trenches, and SiO₂, gold (Au) and platinum (Pt) can be seen. Zoomed EELS map in FIG. 7(c) allowed determination of the thickness due to material contrast, with region labelled SiO₂ indicating the signal from oxygen (corresponds to SiO₂ layer) and line marked with arrows indicating the sp2 carbon EELS shoulder. The observed thickness was uniform across the entire trench, on its top, bottom and sidewall surfaces. 2L ML-AC was 1.45 nm thick, and was disposed uniformly along the intersection between SiO₂ and Au. Material deposition uniformity is highly important for reliable electronic performance, and it is desired to avoid having regions with varying thickness which would lead to varying electrical performance. Thus, the present examples demonstrate uniform deposition of material with thickness of 1.45 nm, thereby advantageously improving uniformity of electrical performance which leads to increased reliability of electronic performance.

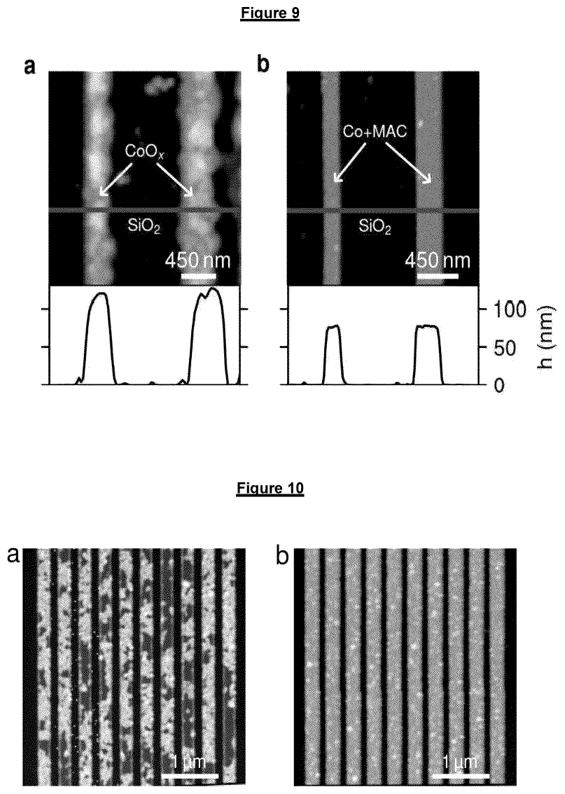

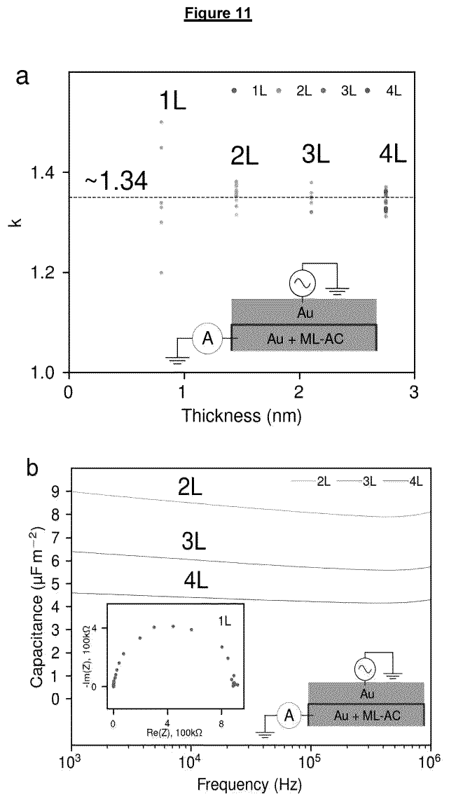

It was further demonstrated that growth also happened across different materials simultaneously. MAC was grown on the surface of cobalt lines with 100 nm width, 60 nm height and a pitch of 0.5 micron, lithographically defined on the Si/SiO₂ substrate shown in FIG. 8(a). The angle between cobalt line sidewall and silicon dioxide substrate was roughly 90 degrees, which corresponded to extreme levels of curvature of 0.6 nm⁻¹. The perfect deposition in such extremely curved regions is challenging for 2D materials due to the lattice-limited possible curvature, which was overcome using the present method and/or material. The data from cross-section TEM (FIG. 8(b)) and EELS (FIG. 8(c)) proved conformal coating of the cobalt line with MAC layer uniformly transiting to the SiO₂ surface passing the corner. 2L ML-AC is 1.45 nm thick, and the 2L ML-AC was disposed uniformly along the intersection between SiO₂, Co and Au.

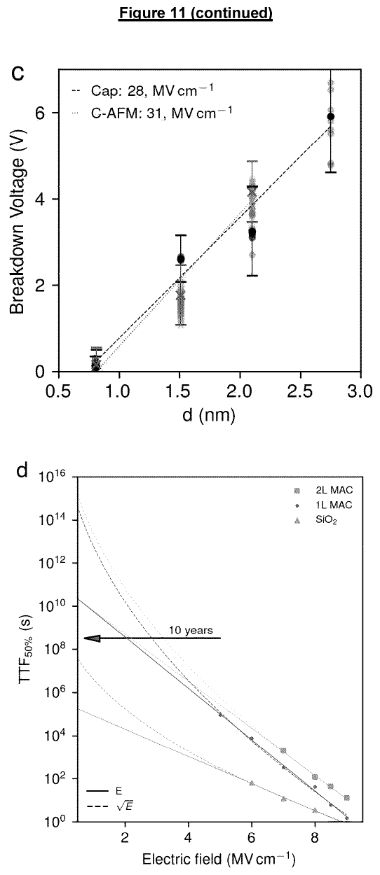

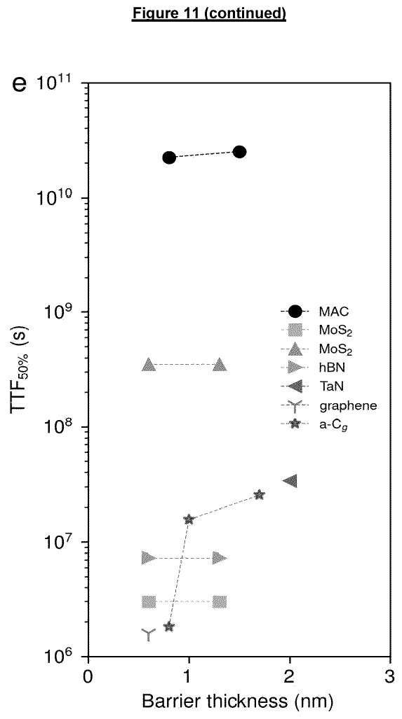

The formed film advantageously does not contain any cracks nor other defects. To prove this, especially on the sidewalls, tests were performed making use of the high sensitivity of cobalt to oxygen and water. Two sets of cobalt electrodes, with and without MAC layer, were left in air for 72 hours. The morphology was analysed with AFM as shown in FIGS. 9(a)-(b) for pristine and protected lines, respectively. From the profile in FIG. 9(a), it can be clearly seen that there was significant expansion of roughly 1.5 times due to the oxidation. In contrast, the thickness of protected lines remained unchanged. Thus, it can be seen that, without MAC protection, the cobalt line expanded due to oxidation. The height (h) was approximately 150 nm. When cobalt lines were protected with MAC, even in the presence of chemical reactions acting on the MAC-protected cobalt lines, the sample did not degrade over time as seen in the bottom part of FIG. 9(b). The height (h) was approximately 75 nm. From these data, it is clear that the MAC deposition formed a continuous and impermeable film to water and oxygen molecules. Similar results were also obtained on Cu lines by testing chemical stability against common copper etchants (FIGS. 10(a) and (b)).

MAC was further evaluated for its potential as an ultra-low-κ dielectric and diffusion barrier. To prove its low κ value, two independent experiments were performed, namely impedance spectroscopy in the low-frequency domain and ellipsometry in the optical range. Permittivity was measured with electronic devices—a set of capacitors with varying dielectric layer thickness. Dependence of the sample impedance on the frequency in the range of 100 Hz to 100 kHz was captured, and dielectric permittivity fitting the data to the L-R/C circuit was further extracted (see FIGS. 11(a) and (b)). For each thickness, at least 30 different samples had K value of 1.3 constant in the frequency range of 1-100 KHz. Thus, it can be seen that the dielectric permittivity remained consistent throughout thickness from 1L to 4L of MAC layer.

Overall, these two independent techniques confirmed that MAC has ultralow-κ values at the thicknesses ranging from 0.6 to 3 nm. The ultra-low κ values were achieved thanks to the amorphous structure and mono-elemental carbon nature of MAC. The apparent thickness independence is observed uniquely to this material.

This can be supported by referring to the NEXAFS data shown in FIG. 3(f). Broadness of the line corresponding to 1s-π transition, and overall weak dependence on the incidence angle when compared to graphene, is typically a reflection of the disorder degree in the system, presence of corrugation, and buckling of layers. Smearing and even weaker sensitivity on the incidence angle of 1s-σ transition also points to random orientation of in-plane bonds organization. π bonds usually involve the delocalized electrons that are free to move across the structure—in a crystalline graphene, they form a “π-cloud” above and below the plane of the carbon atoms, contributing significantly to electronic conduction. In MAC, this π network is disrupted, therefore increasing the relative contribution of the σ bonds to the dielectric permittivity. Dipoles associated with both bonds appear to be negligibly small, and these data indirectly explain the observed ultra-low dielectric permittivity.

Aside from the parasitic capacitive crosstalk, the dielectric used in metallic interconnect stacks should block any breakdown leakage currents between conductive lines and active semiconducting parts. To demonstrate this, conductive AFM of MAC on metal pads was used to measure tunnelling I-V curves and analyse the dielectric strength. Stress-voltage sweeps in capacitors used to extract dielectric permittivity was also performed. The dielectric strength was determined to be up to 28-31 MV cm⁻¹, which is the highest reported among 2D and 3D materials. The data is shown in FIG. 11(c) (Cap=Capacitor=28 MV cm⁻¹ and C-AFM=Conductive Atomic Force Microscopy=31 MV cm⁻¹).

The metal (Cu) interdiffusion barrier performance of MAC layers was measured (FIG. 11(d)) using standard approach statistically analysing current versus time at various applied bias voltages. Time-to-failure (TTF), determined by linear ln(TTF)~E model, at operating fields (~0.5 MV/cm) gave failure times of 1012 s, which outperformed all recently reported and commonly used materials by at least two orders of magnitude (FIG. 11(e)). The negligible changes seen in MAC between the 1L and 2L indicated that metal diffusion failure mechanism was not limited by MAC. The results proved that MAC has an added property, which makes it perfect for new advanced architecture of interconnects stack, an architecture where the low-k dielectric also plays the role of metal ion diffusion barrier.

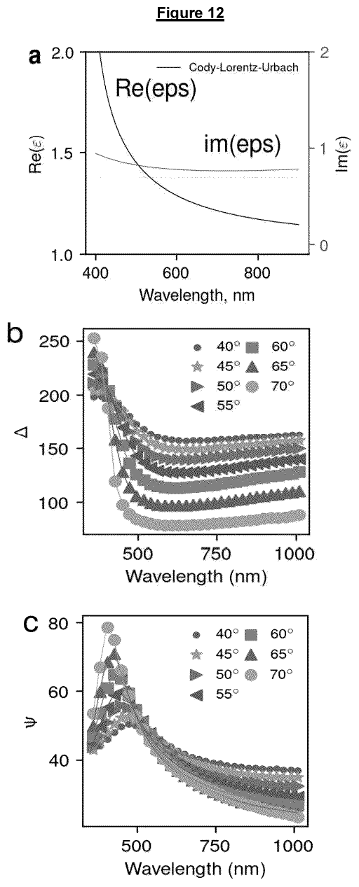

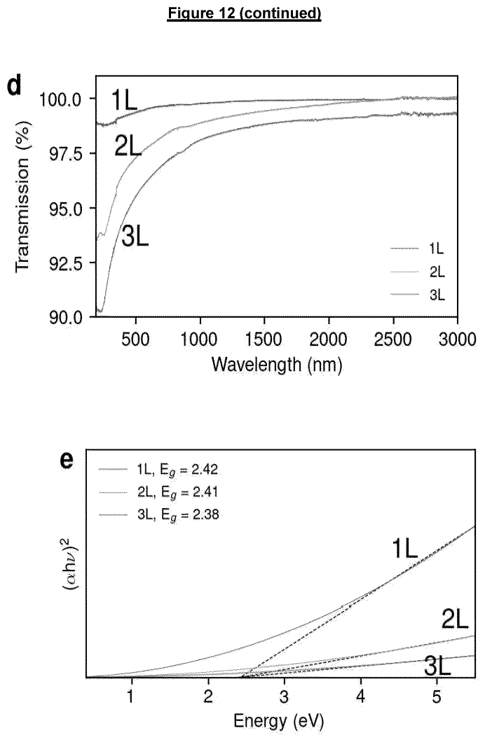

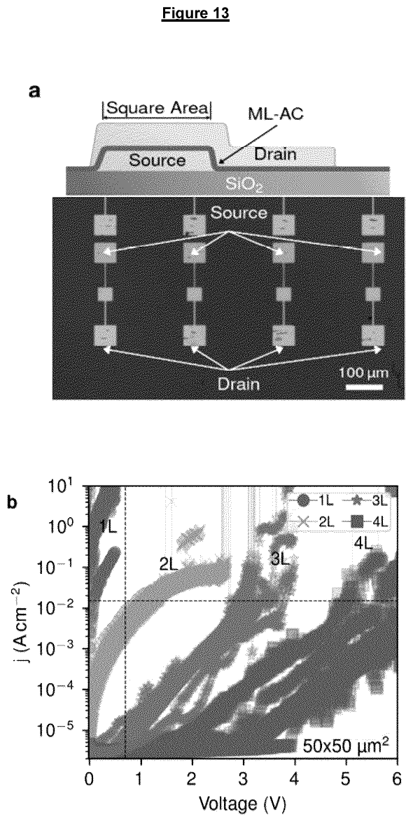

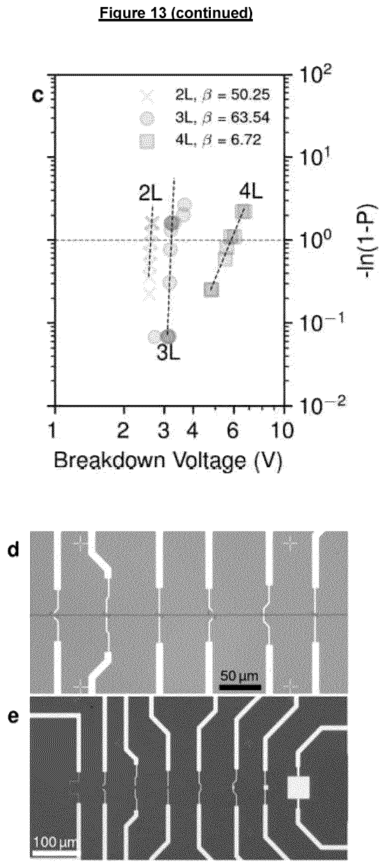

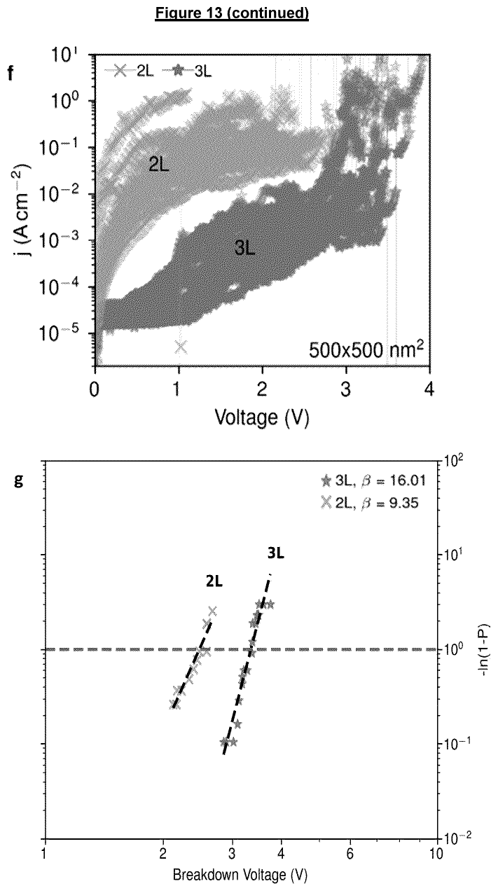

The low-frequency K values were supported by independent ellipsometry data shown in FIG. 12(a). Cody-Lorentz-Urbach model was used to process ψ-Δ spectra collected at 7 different incidence angles (FIGS. 12(b)-(c)). The increase of dielectric permittivity in short UV wavelengths coincided with observed increase of absorption in this range (see FIGS. 12(d)-(e)). Towards lower frequencies, real part of permittivity gradually decreased to the value of roughly 1.3. For MAC, it is also natural to have optical dielectric permittivity slightly larger than that in a low-frequency domain.

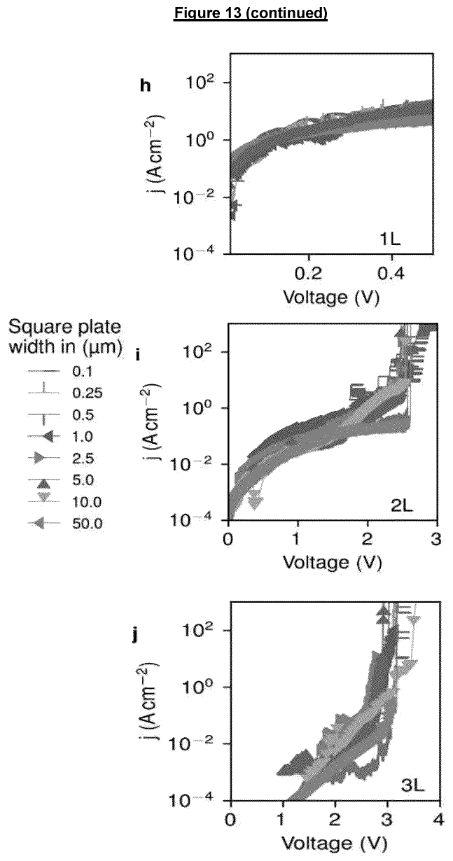

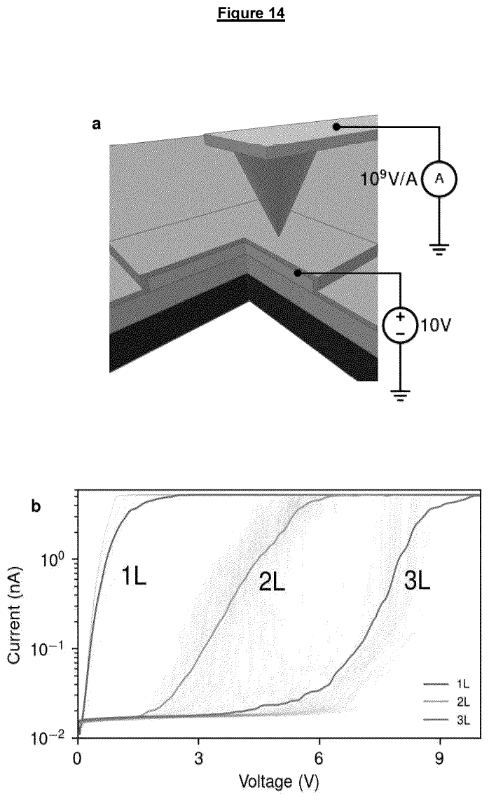

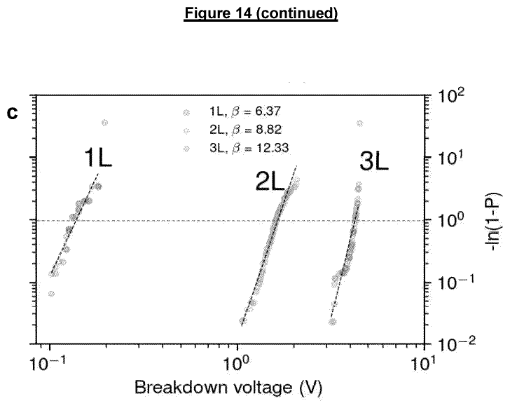

Results of breakdown I-V curves are summarized in FIG. 13. The same devices that were previously employed to measure breakdown voltage (see FIGS. 13(a), (d), and (e)) were used. Breakdown voltages showed consistency across large (50×50 μm², FIG. 13(b)-(c)) and small (500×500 nm², FIGS. 13(f)-(g)) devices, and demonstrated high degree of consistency for different thicknesses and varying capacitor plate size (FIGS. 13(h)-(i)-(j) for 1, 2 and 3 L, respectively). The results show that leakage current and breakdown voltage did not depend significantly on the plate area. These results were also supported by conductive probe AFM I-V curves (FIG. 14(b)) collected from golden metal plates covered with MAC at different thicknesses.

### Applications in Semiconductor Integrated Circuit

MAC is an ideal ultralow-κ dielectric material, meeting the requirement for dielectric, κ<2 (MAC has κ=1.3), and is a perfect barrier layer at 0.6 nm (current existing ultralow-k materials are porous and require barrier to prevent metal diffusion).

Therefore, metal line core width can be maximised with a modified device structure.

With a MAC barrier, since MAC is an ideal dielectric material for the “space width”, liner+barrier is no longer a part of interconnect line width. By combining MAC dielectric with existing ULK dielectric, an increased metal line core width can be achieved.

MAC can also be grown thicker to fully replace ULK dielectric that fills the “space width”, since it outperforms existing dielectric space width material, the space width can be reduced. This further increases the volume of metal line to the maximum possible for improved conductivity. Alternatively, metal volume can remain the same at optimal size, while overall interconnects scaling focus on the reduction of space width. With a huge increase in interconnect metal volume, the bottleneck of interconnects scaling can be solved.

### Applications in Spacer for Gate-All-Around (GAA) Transistors and FinFETs

The spacing between Gate and Source/Drain contact is the main problem limitation for such transistors due to high parasitic capacitance. IRDS roadmap suggests that even though first generation GAA transistor can be realised with 6 nm spacer width and κ=3.3, there is no solution to reduce this 4 nm with κ=2.7. With MAC, a reliable GAA transistor architecture is possible with 2.1 nm and κ=1.3. Furthermore, if needed, the spacer width can be further reduced down up to 0.6 nm (and as thick as 4-6 nm for the whole range of spacer widths). Table 1 shows the possible dimensions for spacer material replaced with MAC.

TABLE 1
Dimensions for spacer material replaced with MAC

| | Spacer | Gate length | Total (2x spacer + gate) |
|---|---|---|---|
| Today | 6 nm, κ = 3.3 | 14 nm | 26 nm |
| 2037 Goal | 4 nm, κ = 2.7 | 12 nm | 20 nm |
| MAC | 2.1 nm, κ = 1.3 | 14 nm | 18 nm |

Other advantages of MAC includes ease of etching and selective etching for high lithography resolution, and MAC being made up of carbon is highly favourable by semiconductor industry for having this feature. Due to amorphous carbon etch chemistry, it can also work as a etch protection layer for fabrication with very low line and side wall roughness. The structure of MAC does not degrade and will provide good performance after going through the fabrication process.

Whilst the foregoing description has described exemplary embodiments, it will be understood by those skilled in the technology concerned that many variations may be made without departing from the present invention.

1. A dielectric material comprising a film comprising a layer of two-dimensional (2D) material, wherein the film has dielectric constant (κ)≤3.0.

2. The dielectric material according to claim 1, wherein the 2D material comprises monolayer amorphous carbon (MAC).

3. The dielectric material according to claim 1, wherein the film has a thickness of ≤20 nm.

4. The dielectric material according to claim 1, wherein the film has a thickness of 0.5-3 nm.

5. The dielectric material according to claim 2, wherein the film comprises at least two layers of 2D MAC.

6. The dielectric material according to claim 2, wherein the film comprises two to five layers of 2D MAC.

7. The dielectric material according to claim 1, wherein the film has a hardness of >10 GPa.

8. The dielectric material according to claim 1, wherein the film has a dielectric strength of >8 MV cm⁻¹.

9. The dielectric material according to claim 1, wherein the film is non-porous.

10. The dielectric material according to claim 1, wherein the film is formed on at least a portion of a non-catalytic substrate.

11. (canceled)

12. (canceled)

13. A method of forming the dielectric material according to claim 1, the method comprising depositing carbon radicals on a non-catalytic substrate.

14. The method according to claim 13, comprising repeating the depositing carbon radicals to form up to five layers of 2D MAC.

15. The method according to claim 13, wherein the depositing carbon radicals comprises forming carbon radicals via photodissociation of a carbon source.

16. The method according to claim 13, wherein the depositing carbon radicals comprises forming carbon radicals via UV wavelength absorption of a carbon source.

17. The method according to claim 16, wherein the UV wavelength is 200-400 nm.

18. The method according to claim 15, wherein the carbon source comprises acetylene, methane, acetylene, ethylene, ethanol, propane, adventitious carbon, or any combination thereof.

19. (canceled)

20. (canceled)

21. The method according to claim 13, wherein the depositing is in a plasma environment.

22. The method according to claim 21, further comprising generating the plasma environment prior to the depositing.

23. The method according to claim 21, wherein the plasma environment comprises remote inductively-coupled plasma.
